(19) United States
(12) Patent Application Publication
(10) Pub. No.: US 2008/0241486 A1
(43) Pub. Date: Oct. 2, 2008

(54) Liquid Crystal Display Device with Evaluation Patterns Disposed Thereon, and Method for Manufacturing the Same

(76) Inventors: Seiji Ishikawa, Kawasaki (JP); Hiroyasu Matsuura, Yokohama (JP); Yuichi Hamamura, Yokohama (JP); Tadamichi Wachi, Fujisawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/055,501

(22) Filed: Mar. 26, 2008

(30) Foreign Application Priority Data
Mar. 30, 2007 (JP) 2007-090190
Oct. 18, 2007 (JP) 2007-271261

(51) Int. Cl. G03F 7/20; B32B 5/00

(52) U.S. Cl. 428/195.1; 430/30

(57) ABSTRACT

Direct exposure equipment having a multiple heads generally conducts overlapping exposure at an exposure area boundary between the heads. In such a case, if the heads are misaligned, a flaw will occur in a pattern shape at an area that is subject to overlapping exposure. To overcome this, TEGs are disposed for evaluating line width and resistance at an overlapping exposure area between the exposure heads and at a returning exposure area formed when direct exposure equipment having a multi-head configuration exposes a substrate. By examining measured values from these TEGs, a misalignment in the multiple exposure heads is detected.

### BACKGROUND OF THE INVENTION

1. Field of the Invention

The present invention relates to technology for maintaining stable exposure performance of direct exposure equipment having a plurality of exposure heads.

2. Description of the Related Art

Liquid crystal display panels are one of the primary applications for the present invention. Such panels are manufactured by aligning and affixing together a thin-film transistor (TFT) panel and a color filter (CF) panel. The TFT and the CF panel are typically manufactured via separate processes. The TFT panel is composed of a glass substrate, upon which are disposed transistors that act as switching elements, capacitors that generate an electrical field for charge, and a circuit connecting these components. The capacitors act as pixels, blocking and transmitting light. It is hard for light to pass through the transistors and the circuit, and therefore these components are often disposed in the vicinity of the pixels. On the CF panel, red, blue, and green photoresist are positioned corresponding to the locations of the pixels on the TFT panel. A light blocker, referred to as a black matrix (BM), is also positioned corresponding to the locations of the transistors and the circuit on the TFT. When aligning and affixing together the TFT and CF, the BM pattern is aligned with the pattern of the light-blocking layer, which consists of the pattern formed by the circuit layer. This is done because, as both the circuit layer pattern and the BM pattern tend to block light, aligning these patterns in an overlapping pattern improves visibility, for example. The circuit layer is formed from Al or similar material.

The formation of these patterns is conducted using a technique known as photolithography. Conventionally this involves using a photomask preformed in the desired pattern, wherein a panel coated with photoresist is exposed through this photomask. After exposure, the pattern is formed using processes such as developing and etching.

At the same time, customer specifications for liquid crystal display panels are becoming increasingly fragmented. It is necessary to create photomasks separately for each customer specification. Consequently, as customer specification fragmentation and high-variety, low-volume manufacturing become more prevalent, mask costs increase. Moreover, work involving ordering the mask also increases. For this reason, direct exposure equipment has been devised, wherein a design pattern is directly exposed without using a mask. One method of realizing direct exposure equipment involves using a spatial light modulator (hereinafter referred to as an SLM) and an optical correlator to irradiate a desired pattern with laser light emitted from a light source. In this case, since an SLM that can cover an entire substrate in a single exposure is not yet commercially viable, the stage is moved while exposing the substrate mounted thereon. The stage is able to move in two dimensions X and Y. Typically, exposure is conducted while moving in the main scan direction, and when this movement ends, the stage is shifted in the sub scan direction. Exposure is not conducted during this movement in the sub scan direction. Then, exposure is conducted again while moving in the main scan direction. Additionally, a method for shortening the time required for exposure has been devised, wherein the SLM and the optical correlator are provided as modular exposure heads. By arranging a plurality of these exposure heads in the sub scan direction and conducting exposure in parallel, the required exposure time is reduced (Patent Documents 1, 2, and 3).

In this exposure method using a plurality of exposure heads, the exposure areas of the respective exposure heads are made to overlap so as not to create gaps between the exposure areas of the exposure heads due to the effects of exposure head alignment error, for example. However, the overlapping portions are thereby exposed twice, and thus it is necessary to lessen the per-exposure intensity compared to that of the non-overlapping portions. In addition, these areas are susceptible to the effects of exposure head alignment adjustments. If such adjustments are not conducted optimally, the desired shape will not be obtained with respect to the patterns of the overlapping portions. Consequently, it is necessary to verify if the above adjustments are being optimally conducted, as well as if deformation due to change with the passage of time has occurred. A proposed method for visualizing the state of the exposure head alignment has been disclosed, wherein a plurality of exposure heads are aligned by the following method. First, a pixel of a first exposure head is turned on, and the position of the exposure beam on the exposed surface is detected using beam position detection means. Subsequently, a pixel of a second exposure head near its adjoining edge is turned on, and the position of the exposure beam from this pixel is detected by the beam position detection means. In so doing, the positions of the pixel of the first exposure head and the pixel of the second exposure head are identified (Patent Document 4). This technology is applied when adjusting the direct exposure equipment, and is not used for evaluating the shape in itself of the pattern of an overlapping exposure area imaged on the substrate during the middle of a production run, for example.

### Patent Document 1: Japanese Unexamined Patent Application Publication No. 2003-345030

### Patent Document 2: Japanese Unexamined Patent Application Publication No. 2007-3934

### Patent Document 3: Japanese Unexamined Patent Application Publication No. 2004-056080

### Patent Document 4: Japanese Unexamined Patent Application Publication No. 2005-1153

Were it simply a matter of the quality of the imaged pattern, one could embed into the substrate a plurality of evaluation elements referred to as test element groups (TEGs), which has been conducted in the manufacture of conventional products. However, unsuccessful pattern formation can not only be attributed to the problem of inadequate exposure head alignment, but also to deformation or other irregularities in the film deposition process and the etching process. Consequently, even when evaluating using TEGs, an imaged pattern evaluation method is necessary wherein deformations detected using the TEGs are easily understood as a problem arising from exposure head alignment, or a problem arising from some other process.

Moreover, in addition to deformations due to misalignments in the relative positions of different exposure heads, deformations can also occur in the imaging result for the same exposure head, due to a mismatch between the back-and-forth movement of the stage and the imaging timing. Means for detecting such deformations in the imaging result are required.

### SUMMARY OF THE INVENTION

In order to solve the above problems, the present invention provides means for verifying the boundaries of the exposure areas due to the exposure heads (hereinafter referred to as the head exposure area boundaries) in an exposure method using a plurality of exposure heads.

First, TEGs for evaluation purposes are disposed upon the head exposure area boundaries. The spacing of the head exposure area boundaries match the spacing of the exposure heads. In addition, the positions of the head exposure area boundaries appearing at the edge of the substrate can be known by taking the offset between the exposure area start positions and the edge of the substrate. In so doing, the area on the substrate corresponding to the head exposure area boundaries can be known in advance. Moreover, by making the TEG larger than the width of a head exposure area boundary, it is possible to confirm the difference between the exposure result at a head exposure area boundary and an imaged portion due to a single exposure head.

When disposing several types of TEGs, the TEGs may be deployed in the main scan direction, as the head exposure area boundaries extend parallel to the main scan direction.

Since the head exposure area boundaries are spaced identically to the spacing of the heads, identical TEGs are disposed at each head exposure area boundary in the sub scan direction.

In addition to a main pattern for evaluating the pattern shape itself, auxiliary patterns showing the position of the head exposure area boundary are disposed in proximity to the main pattern on the TEG for evaluation purposes. In so doing, it is possible to simplify observation.

Moreover, such a pattern is not only disposed at the head exposure area boundary, but is also similarly disposed at the boundary between the exposure areas of the same head caused by the back-and-forth movement of the stage (to be hereinafter referred to simply as the returning boundary). In so doing, imaging deformation at the returning boundary can also be evaluated.

By placing evaluation TEGs upon the head exposure area boundaries, it is possible to detect deformation that occurs at the head exposure area boundaries. If this deformation occurs along the entirety of a single head exposure area boundary, then the cause may be considered an exposure head-related issue, such as the alignment of the exposure heads that imaged the affected head exposure area boundary. If the deformation occurs at all TEGs of the same type positioned upon the head exposure area boundaries in a certain region of the substrate, then it can be determined that an in-plane irregularity in the processing (such as film deposition or etching) of the affected region is causing the problem. In addition, by making the evaluation TEGs larger than the width of a head exposure area boundary, the pattern of the portion jutting from the head exposure area can be compared to the pattern of the portion within the head exposure area. In so doing, deformation within the exposure area boundary can be easily found.

In this way, as proposed in this specification, by distributing evaluation TEGs, deformations occurring upon head exposure area boundaries can be easily detected. Not only that, it becomes possible to determine whether such deformation is truly a problem arising from the exposure heads, or a problem arising from another process, such as film deposition or etching.

Moreover, imaging deformation at the returning boundaries can also be easily detected.

### BRIEF DESCRIPTION OF THE DRAWINGS

FIG. 1 shows head exposure area boundaries and a method for disposing evaluation TEGs;

FIG. 2A shows a relationship between movement of a stage and exposure areas of exposure heads;

FIG. 2B shows the relationship between the movement of the stage and the exposure areas of the exposure heads;

FIG. 2C shows the relationship between the movement of the stage and the exposure areas of the exposure heads;

FIG. 3A shows an example of a plurality of exposure heads misaligned in a vertical direction, as well as line width deformation in an overlapping exposure area due to such misalignment;

FIG. 3B shows an example of a plurality of exposure heads misaligned in the vertical direction, as well as line width deformation in the overlapping exposure area due to such misalignment;

FIG. 3C shows an example of a plurality of exposure heads misaligned in the vertical direction, as well as line width deformation in the overlapping exposure area due to such misalignment;

FIG. 4A shows an example of a plurality of exposure heads whose spacing is misaligned in a sub scan direction, as well as line width deformation in the overlapping exposure area due to such misalignment;

FIG. 4B shows an example of a plurality of exposure heads whose spacing is misaligned in the sub scan direction, as well as line width deformation in the overlapping exposure area due to such misalignment;

FIG. 4C shows an example of a plurality of exposure heads whose spacing is misaligned in the sub scan direction, as well as line width deformation in the overlapping exposure area due to such misalignment;

FIG. 4D shows an example of a plurality of exposure heads whose spacing is misaligned in the sub scan direction, as well as line width deformation in the overlapping exposure area due to such misalignment;

FIG. 4E shows an example of a plurality of exposure heads whose spacing is misaligned in the sub scan direction, as well as line width deformation in the overlapping exposure area due to such misalignment;

FIG. 5A shows an example of a plurality of exposure heads misaligned in a main scan direction, as well as line width deformation in the overlapping exposure area due to such misalignment;

FIG. 5B shows an example of a plurality of exposure heads misaligned in the main scan direction, as well as line width deformation in the overlapping exposure area due to such misalignment;

FIG. 5C shows an example of a plurality of exposure heads misaligned in the main scan direction, as well as line width deformation in the overlapping exposure area due to such misalignment;

FIG. 6 shows a relationship between exposure edges of the exposure heads and the overlapping exposure areas;

FIG. 7A is an exemplary line width evaluation TEG that intersects an overlapping exposure area;

FIG. 7B is an exemplary line width evaluation TEG that intersects an overlapping exposure area;

FIG. 8A is an exemplary line width evaluation TEG that is provided parallel to an overlapping exposure area;

FIG. 8B is an exemplary line width evaluation TEG that is provided parallel to an overlapping exposure area;

FIG. 9A is an exemplary line width evaluation TEG, being a diagonal line that intersects an overlapping exposure area;

FIG. 9B is an exemplary line width evaluation TEG, being a diagonal line that intersects an overlapping exposure area;

FIG. 10 is an exemplary line width evaluation TEG that intersects an overlapping exposure area, being used in the evaluation of a returning exposure area formed by a single exposure head;

FIG. 11 shows a method for manufacturing liquid crystal display panels, the method including head alignment of multi-head exposure equipment using line width evaluation TEGs;

FIG. 12 shows a method for disposing evaluation TEGs on a substrate;

FIG. 13 shows an example of the measurement locations on a line width evaluation TEG;

FIG. 14A shows a way to summarize measured results from line width TEGs;

FIG. 14B shows a way to summarize the measured results from line width TEGs;

FIG. 14C shows a way to summarize the measured results from line width TEGs;

FIG. 15 is an exemplary TEG for measuring resistance, the TEG having a winding shape;

FIG. 16 is an exemplary TEG for measuring resistance, the TEG having a winding shape;

FIG. 17A is an exemplary TEG for measuring resistance, the TEG having a checkered shape;

FIG. 17B is an exemplary TEG for measuring resistance, the TEG having a checkered shape;

FIG. 18A is an exemplary TEG for measuring resistance, the TEG having a diamond shape;

FIG. 18B is an exemplary TEG for measuring resistance, the TEG having a diamond shape;

FIG. 19A is an exemplary TEG for measuring resistance, the TEG having a diamond shape;

FIG. 19B is an exemplary TEG for measuring resistance, the TEG having a diamond shape:

FIG. 20A is an exemplary TEG for measuring resistance, the TEG having a line shape;

FIG. 20B is an exemplary TEG for measuring resistance, the TEG having a line shape;

FIG. 21A is an exemplary TEG for measuring resistance, the TEG having a line shape;

FIG. 21B is an exemplary TEG for measuring resistance, the TEG having a line shape;

FIG. 22 shows a method for manufacturing liquid crystal display panels, the method including head alignment of the multi-head exposure equipment using resistance evaluation TEGs;

FIG. 23 shows an example wherein TEGs are also disposed at the returning boundaries;

FIG. 24 shows a method for detecting misalignment in the sub scan direction by using opposed-rectangle TEGs;

FIG. 25 shows a method for detecting misalignment in the main scan direction by using opposed-rectangle TEGs;

FIG. 26 shows a diagonally-disposed square TEG;

FIG. 27A shows disposition of a box-in-box TEG, as well as a method for detecting misalignment in both the main scan direction and the sub scan direction;

FIG. 27B shows disposition of the box-in-box TEG, as well as a method for detecting misalignment in both the main scan direction and the sub scan direction; and

FIG. 27C shows disposition of the box-in-box TEG, as well as a method for detecting misalignment in both the main scan direction and the sub scan direction.

### DESCRIPTION OF THE PREFERRED EMBODIMENTS

The present invention will now be described with reference to the drawings.

### Embodiment 1

FIG. 1 shows a method for disposing evaluation TEGs in the present invention.

The orientation of a substrate 100 is regulated by an orientation flat 107. Panels 101 are disposed upon this substrate 100. The number of panels disposed upon the substrate is arbitrary. FIG. 1 merely shows a schematic example illustrating a concept, and does not limit factors such as the number of panels. These panels are exposed by the exposure heads 102a, 102b, 102c, and 102d of a piece of exposure equipment. Also with regard to the number of exposure heads, FIG. 1 illustrates the case wherein exposure is conducted with four heads, but the number of heads is not limited to four. These exposure heads are arranged according to a fixed spacing 111. The respective exposure heads conduct a single exposure over a width equal to the head width (HW) 108, as the stage moves in the main scan direction 109. When a single scan ends, the stage moves in the sub scan direction. As a result, the positions of the heads move in the sub scan direction 110 relative to the stage. The entire surface of the substrate 100 is exposed by this repeated movement. TEGs for evaluation purposes are placed upon a boundary 104 between the head 102a and the head 102b, upon a boundary 105 between the head 102b and the head 102c, and upon a boundary 106 between the head 102c and the head 102d. In the present embodiment, the TEGs are placed between products (i.e., on the scribe lines).

For example, evaluation TEGs are placed upon the head exposure area boundary 104 at the positions 103a, 103b, 103c, and 103d of the scribe lines. The other head exposure area boundaries 105 and 106 are similar.

In an actual device, the stage moves while the positions of the heads are fixed. However, for ease of understanding, the following explanation of the scanning method will describe the movement of the relative positions of the heads with respect to the stage position as a basis.

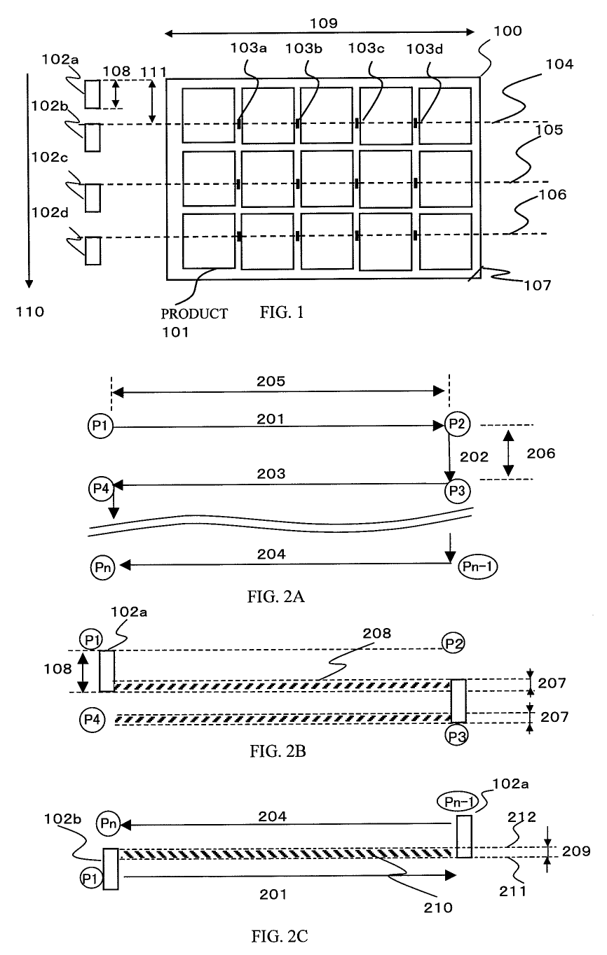

The head scanning method by the movement of the stage is shown in FIG. 2A. Each head moves a movement distance 205 from a position P1 to a position P2 as a result of a scan 201. The scan 201 is parallel to the main scan direction. During the scan 201, the exposure head 102a, the exposure head 102b, the exposure head 102c, and the exposure head 102d conduct exposure. Subsequently, the stage moves a movement distance 206 from P2 to P3 as a result of a scan 202. The scan 202 is parallel to the sub scan direction. During the scan 202, the exposure head 102a, the exposure head 102b, the exposure head 102c, and the exposure head 102d do not conduct exposure. Subsequently, each head moves a movement distance 205 from P3 to P4 as a result of a scan 203. The scan 203 moves in a direction opposite to that of the scan 201. During the scan 203, the exposure head 102a, the exposure head 102b, the exposure head 102c, and the exposure head 102d conduct exposure. Repeating this movement, each head then moves a movement distance 205 from Pn−1 to Pn as a result of a scan 204. In this way, each head moves in a combination of back-and-forth movement in the main scan direction, and movement in the sub scan direction.

Next, the area exposed by one of the exposure heads as a result of the above stage movement will now be described with reference to FIG. 2B. Consider an exposure head 102a by way of example. The exposure head 102a has an exposure head width 108, as shown in FIG. 1. If the exposure head width 108 and the movement distance 206 are made to be the same, then there is a possibility that some areas may not be exposed, due to problems such as mechanical positioning errors. Thus it is typical to make the movement distance 206 in the sub scan direction shown in FIG. 2A shorter than the exposure head width 108 shown in FIG. 1. By making the movement distance 206 shorter than the exposure head width 108, a returning overlapping exposure area (a returning dual exposure area) 208 occurs at the areas exposed during scan 201 and scan 203 by the exposure heads. A returning overlapping exposure area 208 occurs every time an exposure head returns (i.e., every time an exposure head moves in the sub scan direction and subsequently backward in the main scan direction), and the width 207 of this overlapping exposure area is fixed. This area is the returning boundary referred to above.

Next, the area exposed by adjacent exposure heads as a result of the above stage movement will now be described with reference to FIG. 2C. Consider an exposure head 102a and an exposure head 102b by way of example.

When the exposure head 102a moves from point Pn−1 to Pn as a result of the scan 204, the exposure head 102a exposes an area of width equal to the exposure head width 108. A line 211 is the line where exposure by the exposure head 102a ends. Meanwhile, the exposure head 102b also exposes an area of width equal to the exposure head width 108 when moving from point P1 to P2 as a result of the scan 201. A line 212 is the line where exposure by the exposure head 102b starts. The area 210 between this exposure end line 211 and exposure start line 212 (shaded portion) is the area subject to overlapping exposure by two exposure heads, and thus becomes the head exposure area boundary. This area 210 has a width 209.

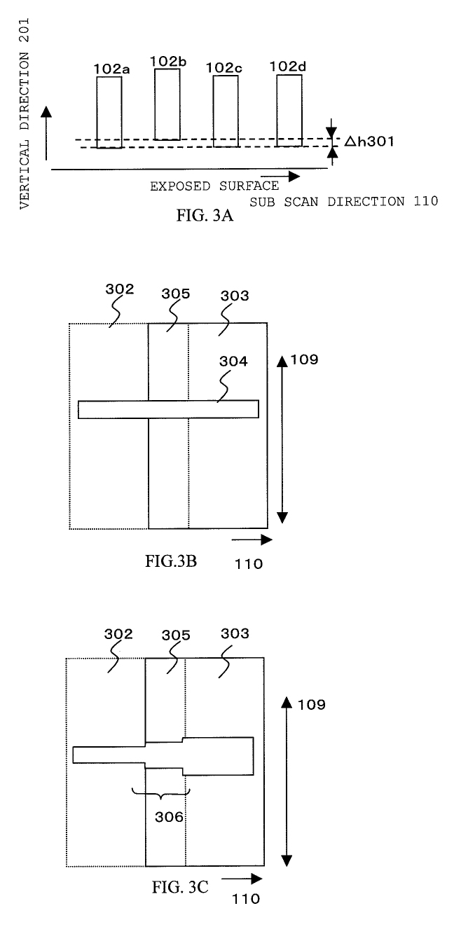

The relative positions of the four exposure heads must be adjusted with a desired degree of precision. An example of vertical exposure head misalignment in the direction is shown in FIG. 3A. When the exposure head 102b is vertically misaligned by a misalignment quantity Δh 301 as compared to the other exposure heads, there is the possibility that the exposure surface will be out of focus. As shown by way of example in FIG. 3B, when imaging a line pattern 304 that straddles the exposure area 302 of the exposure head 102a and the exposure area 303 of the exposure head 102b, errors or variation in the line width will ideally not be seen in the line pattern at the overlapping exposure area 305. However, as shown by way of example in FIG. 3A, if the exposure head 102b is vertically misaligned, then there is the possibility that line width variation 306 will be seen at the overlapping exposure area 305 as shown in FIG. 3C, due to improper focus or similar error. Ideally, such exposure head misalignments should be detected early and while their effects are still insignificant.

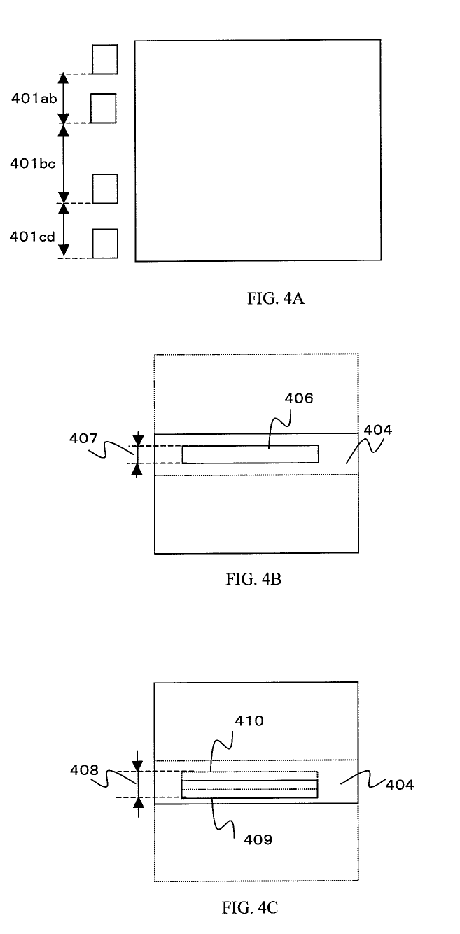

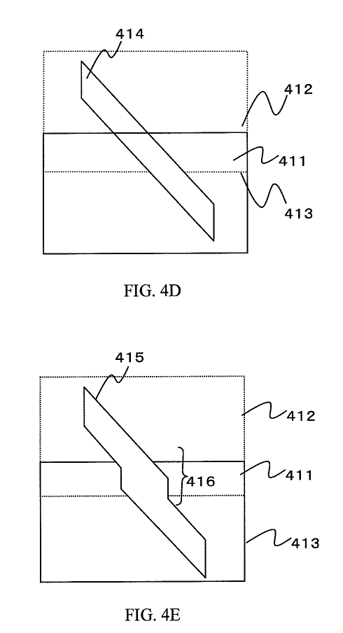

Although it is desirable to dispose the four exposure heads at equal spacing in the sub scan direction, an example of the case wherein the spacing between the exposure heads has become unequal is shown in FIG. 4A. While the interval 401ab and the interval 401cd herein are normal values and equal to each other, the interval 402bc is larger than the intervals described above. In other words, the exposure head 102c has been shifted downwards in the figure from its normal position. This being the case, consider an example wherein a line pattern 406 is imaged in an overlapping exposure area 404, as shown in FIG. 4B. The parameters of the respective exposure heads have been appropriately adjusted such that the ideal shape (the width 407, for example) for the pattern 406 imaged in the overlapping exposure area 404 is obtained in the two exposures by the exposure head 102c and the exposure head 102d. Herein, if the exposure head 102c is shifted towards the exposure head 102d from its predetermined position, then the image 409, imaged by the exposure head 102c, and the image 410, imaged by the exposure head 102d, will be misaligned. For this reason, it is possible that the line width 408 of the generated pattern will differ from the desired width 407.

An example will now be described wherein the diagonal line pattern 414 shown in FIG. 4D is imaged in the case where there is misalignment in the exposure head spacing as shown in FIG. 4A, the diagonal line pattern 414 spanning an overlapping exposure area 411, an exposure area 412 due to the exposure head 102c, and an exposure area 413 due to the exposure head 102d. In this case, if there is misalignment in the exposure head spacing, then an error 416 will occur in the diagonal line pattern 415 at a location corresponding to the overlapping exposure area, as shown in FIG. 4E. Ideally, line width variation such as that shown in FIG. 4C and errors such as that shown in FIG. 4E should be detected early and while their effects are still insignificant.

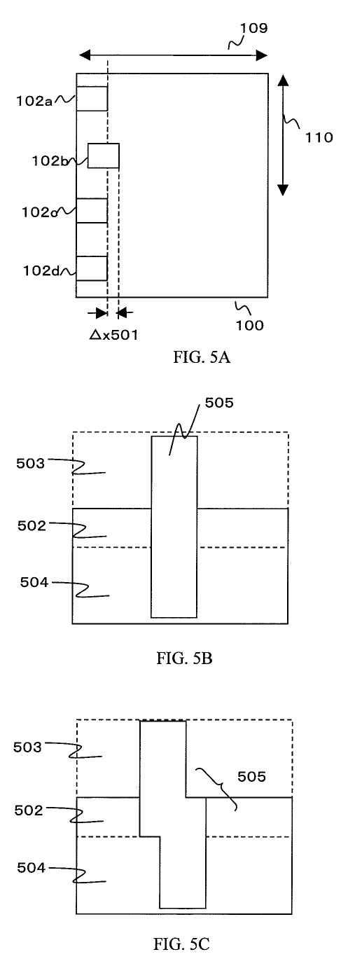

Although it is desirable to dispose the four exposure heads in a straight line perpendicular to the main scan direction, an example wherein the arrangement of the exposure heads has been shifted left or right in the main scan direction is shown in FIG. 5A. In FIG. 5A the exposure head 102a is shifted in the main scan direction by a distance Δx 501 as compared to the other heads. Consider the line pattern 505, shown in FIG. 5B, that spans the exposure area 503 of the exposure head 102c, the exposure area 504 of the exposure head 102d, and the overlapping exposure area 502 of the exposure head 102c and the exposure head 102d. In the case of the misalignment shown in FIG. 5A, it is possible that an error will occur in the line pattern 505 in the vicinity of the overlapping exposure area, like that shown in FIG. 5C. Ideally, such exposure head misalignments should be detected early and while their effects are still insignificant.

When commencing production using a multi-head exposure equipment, the exposure heads are sufficiently aligned to correct the misalignments shown in FIGS. 3A, 4A, and 5A. However, the heads become misaligned over repeated exposures due to factors such as mechanical vibrations and component deterioration. Consequently, production using multi-head exposure equipment requires the establishment of a method to find pattern abnormalities such as those shown in FIGS. 3C, 4C, and 5C early, as well as a method to respond to such abnormalities after being found.

In order to find the above pattern abnormalities, TEGs are distributed in the overlapping exposure areas between heads. In order to find process abnormalities with typical TEGs, the TEGs are disposed in several locations on the substrate surface. Since the head exposure area boundaries of the multi-head exposure equipment appear at fixed areas on the substrate, the TEGs must be disposed on the head exposure boundary portion of the substrate in order to detect the above deformations related to multi-head alignment.

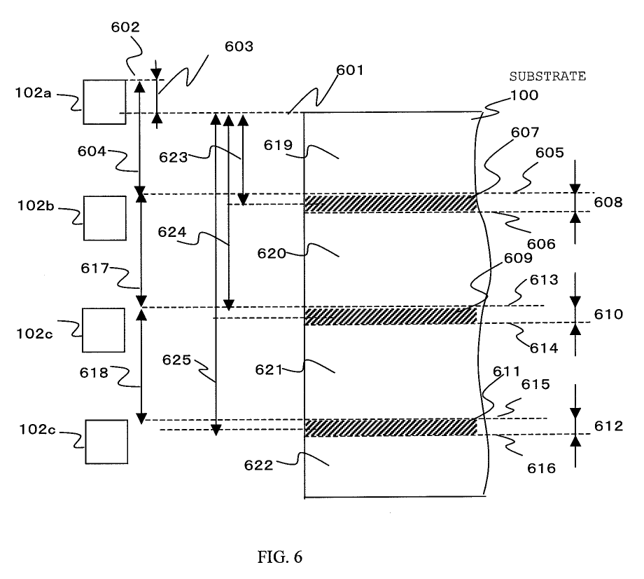

The method for identifying the positions of the head exposure boundary portions appearing on the substrate will now be described with reference to FIG. 6. The following description takes the example of the location of the head exposure boundary of the exposure head 102a and the exposure head 102b on the substrate 100 shown in FIG. 1. The exposure start edge 602 of the exposure head 102a has a fixed offset value (OF) 603 with respect to the substrate edge 601 lying parallel to the main scan direction of the substrate 100. The exposure head 102a exposes an area from an exposure start edge 602 to an exposure end edge 606. The exposure head 102b, being disposed at a head spacing (HD) 604 with the exposure head 102a, starts exposure from an exposure start edge 605. Consequently, the area between the exposure end edge 606 of the exposure head 102a and the exposure start edge 605 of the exposure head 102b (shaded portion) is an overlapping exposure area 607, and is thus the portion that becomes a head exposure area boundary. The area outside the exposure start edge 605 of the exposure head 102b (the upper side of the figure) is the single exposure area 619 of the exposure head 102a. The area between the exposure end edge 606 of the exposure head 102a and the exposure start edge 613 of the exposure head 102c is the single exposure area 620 of the exposure head 102b. The other overlapping exposure areas and single exposure areas are similar.

The width (OW) 608 of the overlapping exposure area is small compared to the exposure head width 111, and is set to be equal to the width 610 of the overlapping exposure area of the exposure head 102b and the exposure head 102c, as well as the width 612 of the overlapping exposure area of the exposure head 102c and the exposure head 102d. Consequently, the distance (Lab) 623 from the substrate edge 601 to the center of the overlapping exposure area 607 of the exposure head 102a and the exposure head 102b becomes

Lab=HD−OF+OW/2 (Equation 1)

The head interval 617 between the exposure head 102b and the exposure head 102c is set to be equal to the interval 618 between the exposure head 102c and the exposure head 102d, as well as the interval 604 between the exposure head 102a and the exposure head 102b.

Consequently, the distance (Lbc) 624 from the substrate edge 601 to the center of the overlapping exposure area 609 of the exposure head 102b and the exposure head 102c becomes

Lbc=2HD−OF+OW/2 (Equation 2)

Similarly, the distance (Lcd) 625 from the substrate edge 601 to the center of the overlapping exposure area 611 of the exposure head 102c and the exposure head 102d becomes

Lcd=3HD−OF+OW/2 (Equation 3)

In this way, the positions of the overlapping exposure areas (i.e., the head exposure area boundaries) on the substrate can be evaluated.

The TEGs that are disposed in the vicinity of the overlapping exposure area will now be described. In the following description, the overlapping exposure area of the exposure head 102a and the exposure head 102b shown in FIG. 6 is taken by way of example as the overlapping exposure area. Other overlapping exposure areas may be considered as similar.

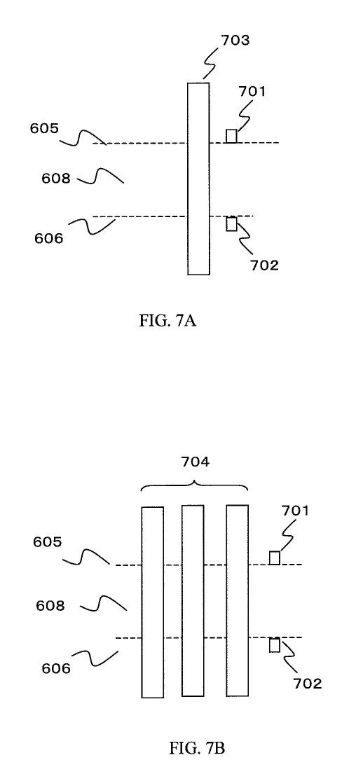

FIG. 7A shows a line pattern 703 that intersects the exposure start line 605 of the exposure head 102b and the exposure end line 606 of the exposure head 102a. Respectively disposed in the vicinity of the exposure start line 605 of the exposure head 102b and the exposure end line 606 of the exposure head 102a are an auxiliary pattern 701 and an auxiliary pattern 702 that indicate the overlapping exposure area 607. These auxiliary patterns serve as markers when observing the substrate using a metallurgical microscope, for example. In so doing, it is possible to detect deformations such as those shown in FIGS. 3C and 5C. Although FIG. 7A shows an example wherein a single line pattern is disposed, FIG. 7B shows an example wherein, instead of the single line pattern 703, parallel line patterns are disposed. In this case it is also possible to detect deformations such as those shown in FIGS. 3C and 5C.

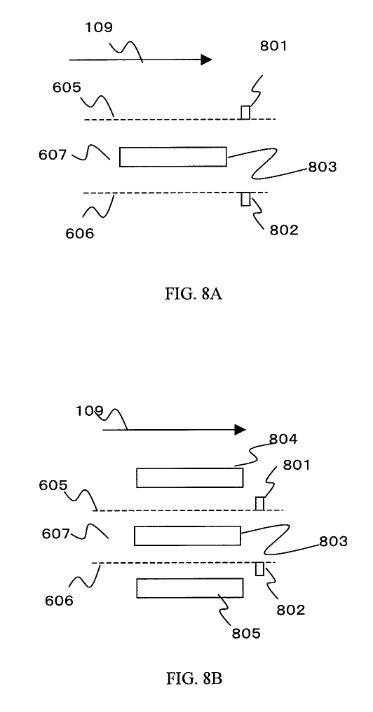

FIG. 8A shows a line pattern 803 existing within an overlapping exposure area and parallel to both the exposure start line 605 of the exposure head 102b and the exposure end line 606 of the exposure head 102a. The line pattern 803 extends in the main scan direction 109. Respectively disposed in the vicinity of the exposure start line 605 of the exposure head 102b and the exposure end line 606 of the exposure head 102a are an auxiliary pattern 801 and an auxiliary pattern 802 that indicate the overlapping exposure area 607. These auxiliary patterns serve as markers when observing the substrate using a metallurgical microscope, for example. In so doing, it is possible to detect deformations such as those shown in FIG. 4C.

FIG. 8B is an example wherein a line pattern 804 similar to the line pattern 803 shown in FIG. 8A is disposed on the outer side of the exposure start line 605 of the exposure head 102b, and wherein a line pattern 805 similar to the line pattern 803 is disposed on the outer side of the exposure end line 606 of the exposure head 102a.

In so doing, it becomes simple to detect deformations appearing in the line pattern 803 by comparing the line pattern 803 to the line pattern 804 and the line pattern 805. If an abnormality such as a broad line width appears with respect to the line pattern 803 in FIG. 8B, then the cause of the deformation is head misalignment as described with reference to FIG. 4C. However, if the line widths are also broad for the line pattern 804 and the line pattern 805, then uneven thickness of the resist film or uneven thickness in film deposition may be considered to be the cause.

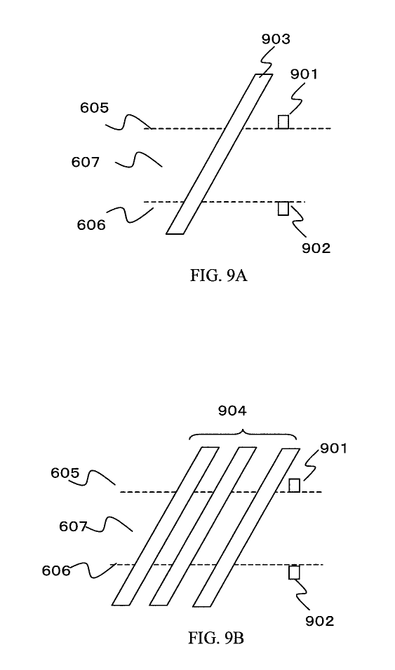

FIG. 9 shows a diagonal line pattern 903 that intersects the exposure start line 605 of the exposure head 102b as well as the exposure end line 606 of the exposure head 102a. Respectively disposed in the vicinity of the exposure start line 605 of the exposure head 102b and the exposure end line 606 of the exposure head 102a are an auxiliary pattern 901 and an auxiliary pattern 902 that indicate the overlapping exposure area 607. These auxiliary patterns serve as markers when observing the substrate using a metallurgical microscope, for example. In so doing, it is possible to detect deformations such as those shown in FIGS. 3C, 4E, and 5C. While FIG. 9A shows an example wherein a single diagonal line pattern is disposed, FIG. 9B shows an example wherein, instead of the diagonal single line pattern 903, parallel diagonal line patterns are disposed. In this case it is also possible to detect deformations such as those shown in FIGS. 3C, 4E, and 5C.

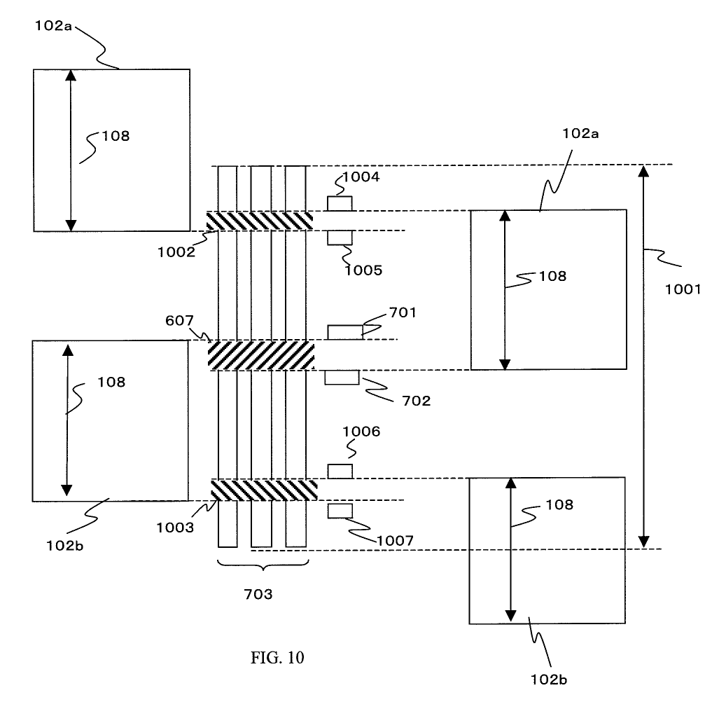

FIG. 10 is an example wherein further modifications have been made to the application of the parallel line patterns shown in FIG. 7B.

The characteristic feature of the example shown in FIG. 10 is that the length (Ltg) 1001 of the parallel line patterns 703 satisfies

Ltg>2HW−OW (Equation 4)

with respect to the exposure head width (HW) 108 and the overlapping exposure area width (OW) 608.

By prescribing the length (Ltg) 1001 of the parallel line patterns 703 as above, the parallel line patterns 703 intersect not only the overlapping exposure area 607 of the exposure head 102a and the exposure head 102b, but also the overlapping exposure area 1002, which is formed when the exposure head 102a returns, as well as the overlapping exposure area 1003, which is formed when the exposure head 102b returns. In so doing, it becomes possible to inspect exposure conditions in each of the areas. The overlapping exposure area 1002 that is formed when the exposure head 102a returns corresponds to the returning overlapping exposure area 208 in FIG. 2B. At this point, if an auxiliary pattern 1004 and an auxiliary pattern 1005 are disposed indicating the location of the returning overlapping exposure area of the exposure head 102a, then it becomes simple to observe the location of the returning overlapping exposure area of the exposure head 102a with a metallurgical microscope or similar instrument. Similarly, by disposing an auxiliary pattern 1006 and an auxiliary pattern 1007 that indicate the location of the returning overlapping exposure area of the exposure head 102b, it becomes simple to observe the location of the returning overlapping exposure area of the exposure head 102b with a metallurgical microscope or similar instrument.

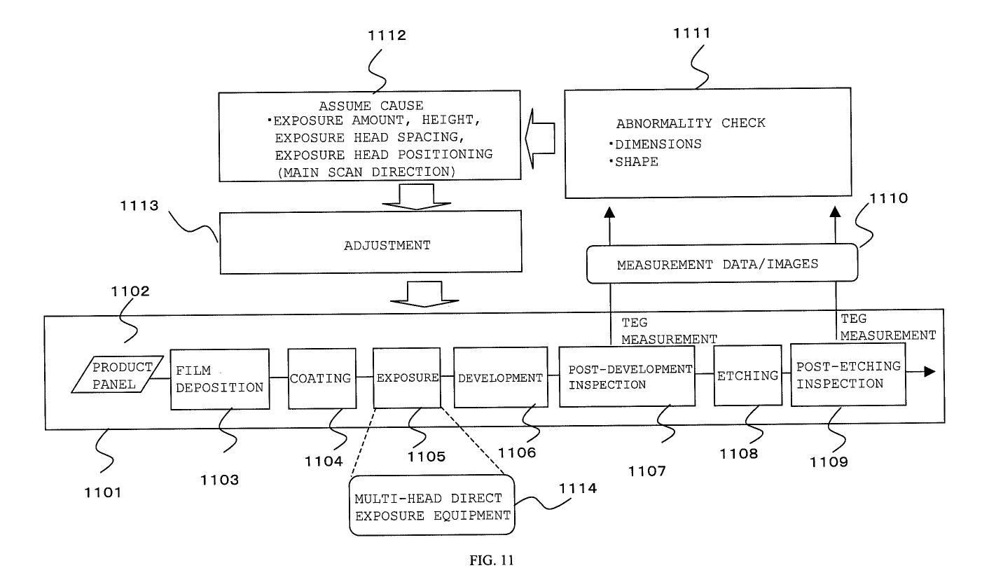

FIG. 11 illustrates the substrate production method using TEGs described in the foregoing. After being loaded onto a production line 1101, a product substrate 1102 is subjected to repeated treatments, including film deposition 1103, coating 1104, exposure 1105, developing 1106, post-developing inspection 1107, etching 1108, and post-etching inspection 1109. The substrate is then taken off the production line after the prescribed treatments have ended. In the exposure treatment 1105 herein, multi-head exposure equipment 1114 is used. This multi-head exposure equipment 1114 has undergone prescribed adjustment procedures, and operates in a production line. Originally, there are no misalignments like those shown in FIGS. 3A, 4A, and 5A. However, during the repeated treatments of the substrate, it is possible that misalignments may occur like those shown in FIGS. 3A, 4A, and 5A, the cause being mechanical vibration, inadvertent operation, or some kind of accident. Consequently, it is necessary to routinely check whether such misalignments have occurred. Thus, as shown in FIG. 1, evaluation TEGs may be disposed upon the head exposure area boundaries to check the processed shape. The evaluation TEGs are disposed upon the head exposure area boundary 104 at the locations 103a, 103b, 103c, and 103d, for example. Evaluation TEGs are similarly disposed upon the head exposure area boundary 105 and the head exposure area boundary 106. The disposed evaluation TEGs shown in FIGS. 7A, 7B, 8A, 8B, 9A, 9B, 10A, and 10B are disposed in the locations described above. These TEGs may for example be all disposed at location 103a, or distributed at the locations 103a, 103b, 103c, and 103d, for example.

If evaluation TEGs of the same type are distributed at a plurality of points on the respective head exposure area boundaries, then it becomes possible to detect abnormalities in treatment processes other than exposure, such as film deposition and etching, since the TEGs are disposed over the entire substrate. In addition, it becomes possible to separate the causes of deformations seen in the evaluation TEG patterns as being exposure head misalignment or an abnormality in a treatment process other than exposure.

The method for evaluating manufacturing processes and head positioning misalignments of the multi-head exposure equipment will now be described, taking by way of example the case wherein a plurality of TEGs having the parallel line patterns shown in FIG. 7B are disposed upon the substrate.

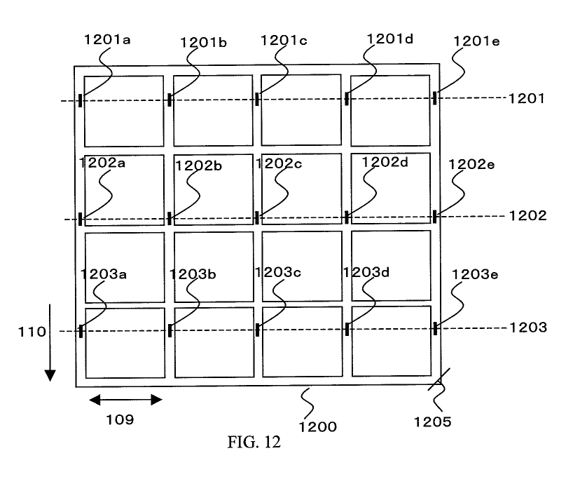

FIG. 12 shows the method for disposing TEGs in the example of a line pattern.

The orientation of a substrate 1200 is regulated by an orientation flat 1205, with a main scan direction 109 and a sub scan direction 110 of the stage. In addition, the rectangles on the substrate 1200 indicate individual product panels. As described above, in the case where the direct exposure equipment has four exposure heads, three head exposure area boundaries 1201, 1202, and 1203 appear upon the substrate 1200. As shown in FIG. 6, the respective head exposure area boundaries are areas of overlapping exposure, and have a fixed width.

Evaluation TEGs are respectively disposed between products upon the head exposure are boundary 1201. The disposed locations are, from the left side of the figure, 1201a, 1201b, 1201c, 1201d, and 1201e. The number of locations whereupon these TEGs are disposed may be suitably modified according to the number of products on the substrate. Evaluation TEGs are also disposed upon the head exposure area boundary 1202 and the head exposure area boundary 1203 at locations corresponding to the locations of the evaluation TEGs disposed upon the head exposure area boundary 1201.

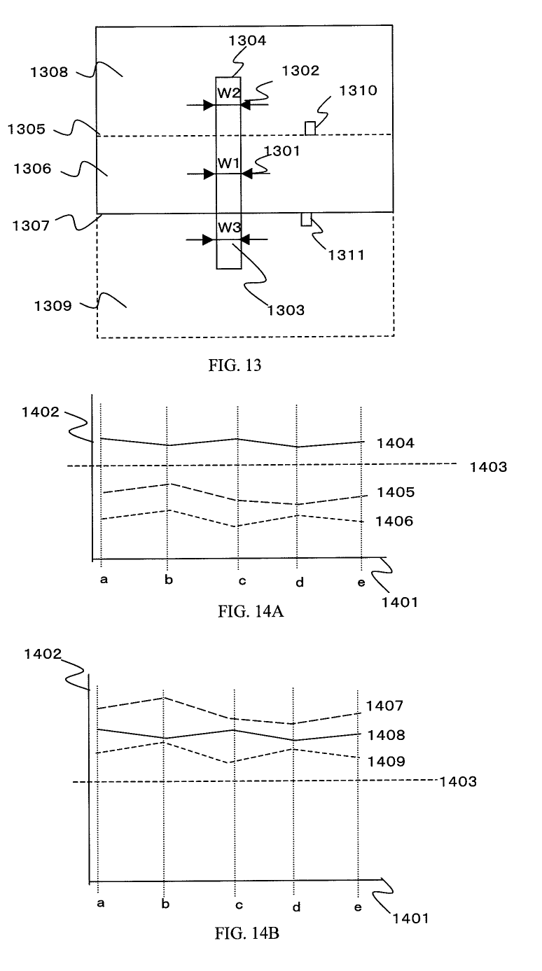

An exemplary method for finding abnormalities in exposure head alignment using evaluation TEGs will now be described, taking the line pattern shown in FIG. 13 as the disposed evaluation TEG.

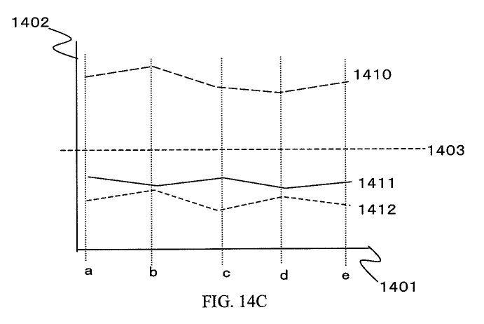

In FIG. 13, a line pattern 1304 is disposed, the pattern extending from a single exposure area 1308 to a single exposure area 1309 and intersecting an overlapping exposure area 1306. Respectively disposed in the vicinity of the overlapping exposure area boundaries 1305 and 1307 are auxiliary patterns 1310 and 1311. In so doing, it becomes simple to observe and locate the boundaries when measuring. The line pattern 1304 is used for measuring a line width (W1) 1301 within the overlapping exposure area 1306, a line width (W2) 1302 within the single exposure area 1308, and a line width (W3) within the single exposure area 1309. The line pattern 1304 shown in FIG. 13 is used to measure line width within an overlapping exposure area and line width within single exposure areas, such measurements being conducted at the points where evaluation TEGs are disposed on the substrate as shown in FIG. 12. Sampling inspection of a reasonable number of points where evaluation TEGs are disposed on the substrate may also be conducted. The results obtained by measuring evaluation TEGs on the substrate are summarized by way of example in FIGS. 14A 14B, and 14C. In FIG. 14A, the horizontal axis 1401 is the location of evaluation TEGs in the main scan direction, while the vertical axis 1402 is the line width. Measured values of the line width W1 are plotted, line 1404 being the line widths W1 of the evaluation TEGs on the head exposure area boundary 1201, line 1405 being the line widths W1 of the evaluation TEGs on the head exposure area boundary 1202, and line 1406 being the line widths W1 of the evaluation TEGs on the head exposure area boundary 1203, as shown in FIG. 12. A reference value 1403 is a predefined value, wherein it is determined that an abnormality exists in exposure head alignment when the line widths exceed the reference value 1403. Herein it can be seen that the line widths W1 exceed the reference value within the overlapping exposure area at the exposure area boundary 1201, which corresponds to the line 1404. The values for the line widths W1, W2, and W3 in this exposure area boundary 1201 are summarized in FIG. 14B. The horizontal axis, vertical axis, and reference value in FIG. 14B is the same as those of FIG. 14A. The lines 1407, 1408, and 1409 indicate the values of the line widths W1, W2, and W3, respectively. If the lines 1407, 1408, and 1409 all exhibit values larger than the reference value as shown in FIG. 14B, then this means that line widths are exceeding the reference value even in the single exposure areas. Therefore, the problem lies not in the exposure head alignment of the direct exposure equipment, but rather it can be determined that an abnormality exists in the processes of film deposition or resist coating, possibly non-uniformity in the film deposition thickness or non-uniformity in the resist thickness.

If the results of the values of the line widths W1, W2, and W3 at the exposure area boundary corresponding to that of the line 1404 are like those summarized in FIG. 14C, wherein only the values for the line width W1 as indicated by the line 1410 exceed the reference value 1403, then one can conclude that the cause of this deformation is an exposure head misalignment.

It should be appreciated that the measurement of the line width (W2) 1302 or the line width (W3) 1303 may also be omitted. In such a case, it is only determined whether or not the line width W1 within the overlapping exposure area exceeds the reference value at the exposure area boundary 1201 corresponding to the line 1404. Thus, in the case where the reference value is exceeded, it can be determined that there is at least either a problem in the exposure head alignment of the direct exposure equipment, or a problem in the uniformity of film deposition thickness or the uniformity of resist thickness.

In addition, the process of measuring the above line widths and comparing them to a threshold value can be achieved by measuring using a computer based on photographs from a microscope, and then comparing the measured values to a reference value stored in memory in advance.

### Embodiment 2

In the first embodiment, a method was disclosed wherein problems in exposure head alignment are detected by measuring the line widths of evaluation TEGs. The second embodiment will disclose a method wherein problems in exposure head alignment are detected by measuring the resistance of the evaluation TEGs.

If film thickness is nearly uniform, then line width and resistance exist in an inverse relationship. Consequently, it is possible to configure in advance a reference value for resistance fluctuation similar to line width fluctuation for the respective TEGs for resistance measurement to be hereinafter described.

Since the method of disposing the evaluation TEGs on the substrate is the same, the shape and other features of the TEGs for resistance measurement will now be described.

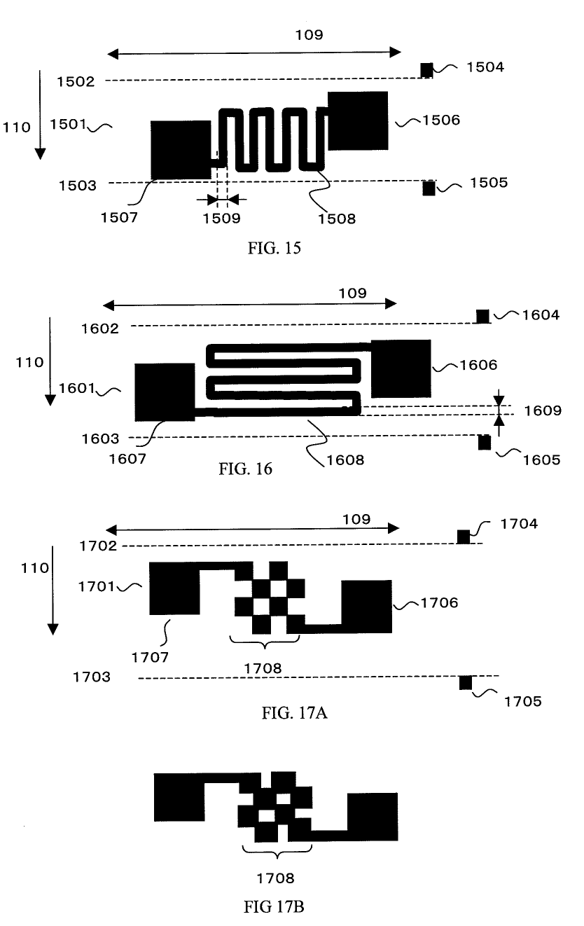

The TEG shown in FIG. 15 detects irregularities in head positioning in the vertical direction as described with reference to FIG. 3A, as well as irregularities in head positioning in the main scan direction 109 as described with reference to FIG. 5A.

A circuit 1508 having a winding shape is provided within an overlapping exposure area 1501, and is connected to a pad 1506 and a pad 1507 for measuring resistance. In addition, respectively disposed in the vicinity of the boundary lines 1502 and 1503 of the overlapping exposure area are auxiliary patterns 1504 and 1505 that indicate the overlapping exposure area. In so doing, it becomes simple to detect the location of the overlapping exposure area when measuring. A characteristic feature of the present TEG is the fact that the winding circuit 1508 is long in the sub scan direction 110. When there exists an irregularity in head positioning in the vertical direction as described with reference to FIG. 3A, or an irregularity in head positioning in the main scan direction 109 as described with reference to FIG. 5A, the line width 1509 fluctuates. For this reason, it is possible to detect exposure head misalignment as a change in the resistance between the pad 1506 and the pad 1507. The number of windings is designed such that the resistance of the winding circuit 1508 exists in an easily-detectable range.

The TEG shown in FIG. 16 detects irregularities in head positioning in the vertical direction as described with reference to FIG. 3A, as well as irregularities in head spacing in the sub scan direction 110 as described with reference to FIG. 4A.

A circuit 1608 having a winding shape is provided within an overlapping exposure area 1601, and is connected to a pad 1606 and a pad 1607 for measuring resistance. In addition, respectively disposed in the vicinity of the boundary lines 1602 and 1603 of the overlapping exposure area are auxiliary patterns 1604 and 1605 that indicate the overlapping exposure area. In so doing, it becomes simple to detect the location of the overlapping exposure area when measuring. A characteristic feature of the present TEG is the fact that the winding circuit 1608 is long in the main scan direction 109. When there exists an irregularity in head positioning in the vertical direction as described with reference to FIG. 3A, or an irregularity in head spacing in the sub scan direction 110 as described with reference to FIG. 4A, the line width 1609 fluctuates. For this reason, it is possible to detect exposure head misalignment as a change in the resistance between the pad 1606 and the pad 1607. The number of windings is designed such that the resistance of the winding circuit 1608 exists in an easily-detectable range.

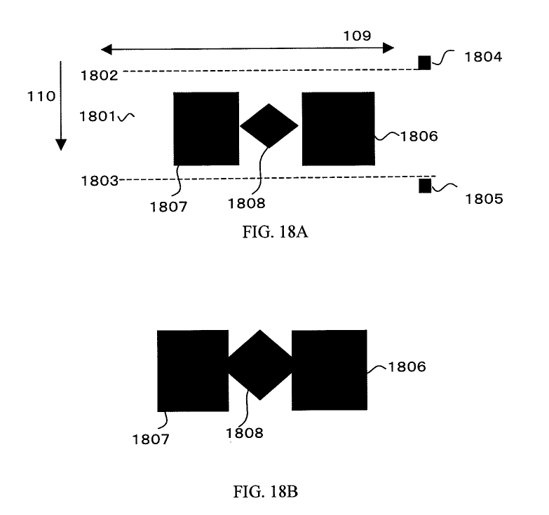

The TEG shown in FIG. 17 detects irregularities in head positioning in the vertical direction as described with reference to FIG. 3A, irregularities in head spacing in the sub scan direction 110 as described with reference to FIG. 4A, as well as irregularities in head positioning in the main scan direction 109 as described with reference to FIG. 5A.

A checkered pattern 1708 is provided within an overlapping exposure area 1701, and is connected to a pad 1706 and a pad 1707 for measuring resistance. In addition, respectively disposed in the vicinity of the boundary lines 1702 and 1703 of the overlapping exposure area are auxiliary patterns 1704 and 1705 that indicate the overlapping exposure area. In so doing, it becomes simple to detect the location of the overlapping exposure area when measuring. A characteristic feature of the present TEG is the fact that, when processed correctly, the cells in the checkered pattern 1708 are connected to each other only at their vertices. For this reason, when the checkered pattern 1708 is processed correctly, the resistance between the pad 1706 and the pad 1707 is extremely large. However, when there occurs an irregularity in head positioning in the vertical direction as described with reference to FIG. 3A, an irregularity in head spacing in the sub scan direction 110 as described with reference to FIG. 4A, or an irregularity in head positioning in the main scan direction 109 as described with reference to FIG. 5A, then the checkered pattern becomes indistinct, and the places of contact between cells in the pattern are no longer points but areas having width, as shown in FIG. 17B. In this case, the resistance between the pad 1706 and the pad 1707 is decreased. It is thus possible to detect irregularities in head positioning using this change in resistance. The number of cells in the checkered pattern 1708 is designed such that the resistance of the pattern exists in an easily-detectable range.

The TEG shown in FIG. 18A detects irregularities in head positioning in the vertical direction as described with reference to FIG. 3A, as well as irregularities in head positioning in the main scan direction 109 as described with reference to FIG. 5A.

A diamond-shaped pattern 1808 is provided within an overlapping exposure area 1801, and the vertices of the diamond-shaped pattern 1808 are connected to a pad 1806 and a pad 1807 for measuring resistance. A characteristic feature of this TEG is the fact that the pads 1806 and 1807 for measuring resistance as well as the diamond-shaped pattern 1808 are arranged in the main scan direction 109. In addition, respectively disposed in the vicinity of the boundary lines 1802 and 1803 of the overlapping exposure area are auxiliary patterns 1804 and 1805 that indicate the overlapping exposure area. In so doing, it becomes simple to detect the location of the overlapping exposure area when measuring. The present evaluation TEG is such that, when processed correctly, only the vertices of the diamond-shaped pattern 1808 are connected to the pad 1806 and the pad 1807. For this reason, when the checkered pattern 1808 is processed correctly, the resistance between the pad 1806 and the pad 1807 is extremely large. However, when there occurs an irregularity in head positioning in the vertical direction as described with reference to FIG. 3A, or an irregularity in head positioning in the main scan direction 109 as described with reference to FIG. 5A, then the diamond-shaped pattern becomes indistinct. Thus the place of contact between the diamond-shaped pattern 1808 and the pad 1806, as well as between the diamond-shaped pattern 1808 and the pad 1807 are no longer points but areas having width, as shown in FIG. 18B. In this case, the resistance between the pad 1806 and the pad 1807 is decreased. It is thus possible to detect irregularities in head positioning using this change in resistance.

The size of the diamond-shaped pattern 1808 is designed such that the resistance change between the pad 1806 and the pad 1807 exists in an easily-detectable range.

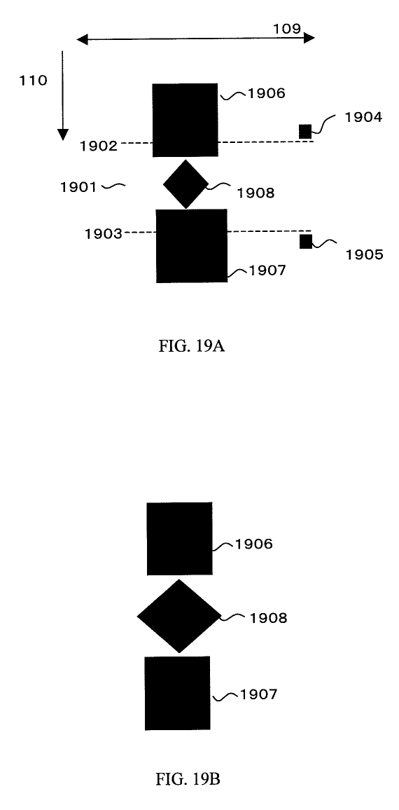

The TEG shown in FIG. 19A detects irregularities in head positioning in the vertical direction as described with reference to FIG. 3A, as well as irregularities in head positioning in the sub scan direction 110 as described with reference to FIG. 4A.

A diamond-shaped pattern 1908 is provided within an overlapping exposure area 1901, and the vertices of the diamond-shaped pattern 1908 are connected to a pad 1906 and a pad 1907 for measuring resistance. A characteristic feature of this TEG is the fact that the pads 1906 and 1907 for measuring resistance as well as the diamond-shaped pattern 1908 are arranged in the sub scan direction 110. In addition, respectively disposed in the vicinity of the boundary lines 1902 and 1903 of the overlapping exposure area are auxiliary patterns 1904 and 1905 that indicate the overlapping exposure area. In so doing, it becomes simple to detect the location of the overlapping exposure area when measuring. The present evaluation TEG is such that, when processed correctly, only the vertices of the diamond-shaped pattern 1908 are connected to the pad 1906 and the pad 1907. For this reason, when the checkered pattern 1908 is processed correctly, the resistance between the pad 1906 and the pad 1907 is extremely large. However, when there occurs an irregularity in head positioning in the vertical direction as described with reference to FIG. 3A, or an irregularity in head positioning in the sub scan direction 110 as described with reference to FIG. 4A, then the diamond-shaped pattern becomes indistinct. As a result, the places of contact between the diamond-shaped pattern 1908 and the pad 1906, as well as between the diamond-shaped pattern 1908 and the pad 1907 are no longer points but areas having width, as shown in FIG. 19B. In this case, the resistance between the pad 1906 and the pad 1907 is decreased. It is thus possible to detect irregularities in head positioning using this change in resistance.

The size of the diamond-shaped pattern 1908 is designed such that the resistance change between the pad 1906 and the pad 1907 exists in an easily-detectable range.

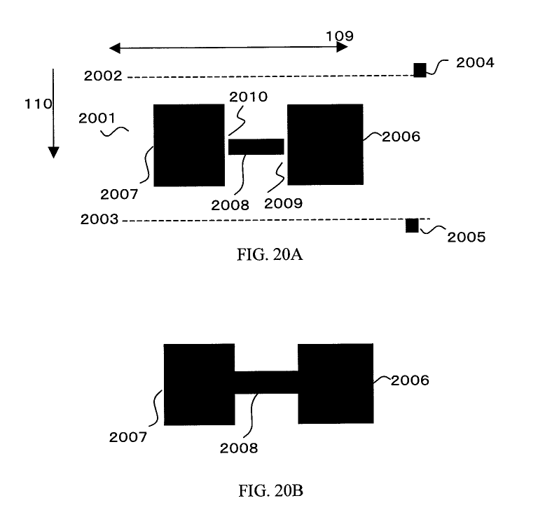

The TEG shown in FIG. 20A detects irregularities in head positioning in the vertical direction as described with reference to FIG. 3A, as well as irregularities in head positioning in the main scan direction 109 as described with reference to FIG. 5A.

A circuit 2008 is provided within an overlapping exposure area 2001. A characteristic feature of this TEG is the fact that a pad 2006 and a pad 2007 for measuring resistance, as well as the circuit 2008, are arranged in the main scan direction 109. A gap 2009 is provided between the pad 2006 and the circuit 2008, and a gap 2010 is provided between the pad 2007 and the circuit 2008. In addition, respectively disposed in the vicinity of the boundary lines 2002 and 2003 of the overlapping exposure area are auxiliary patterns 2004 and 2005 that indicate the overlapping exposure area. In so doing, it becomes simple to detect the location of the overlapping exposure area when measuring. The present evaluation TEG is such that, when the circuit 2008 is processed correctly, the resistance between the pad 2006 and the pad 2007 is extremely large due to the gap 2009 and the gap 2010. However, when there occurs an irregularity in head positioning in the vertical direction as described with reference to FIG. 3A, or an irregularity in head positioning in the main scan direction 109 as described with reference to FIG. 5A, then the circuit 2008 becomes indistinct. As a result, the gap 2009 and the gap 2010 are eliminated, as shown in FIG. 20B. In this case, the resistance between the pad 2006 and the pad 2007 is decreased. It is thus possible to detect irregularities in head positioning using this change in resistance.

The size of the gaps 2009 and 2010 are designed such that the resistance change between the pad 2006 and the pad 2007 exists in an easily-detectable range.

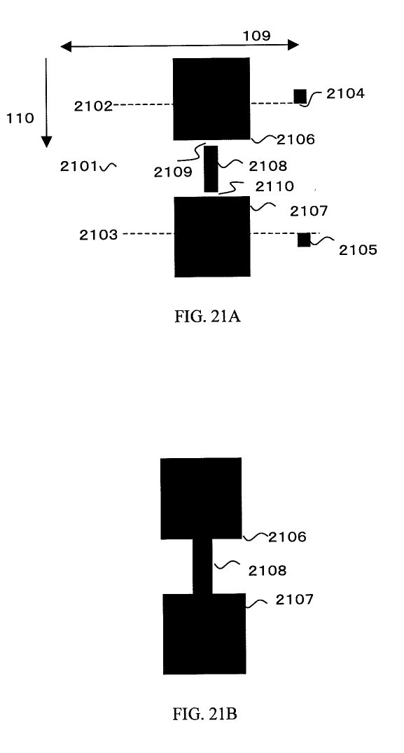

The TEG shown in FIG. 21A detects irregularities in head positioning in the vertical direction as described with reference to FIG. 3A, as well as irregularities in head positioning in the sub scan direction 110 as described with reference to FIG. 4A.

A circuit 2108 is provided within an overlapping exposure area 2101. A characteristic feature of this TEG is the fact that a pad 2106 and a pad 2107 for measuring resistance, as well as the circuit 2108, are arranged in the sub scan direction 110. A gap 2109 is provided between the pad 2106 and the circuit 2108, and a gap 2110 is provided between the pad 2107 and the circuit 2108. In addition, respectively disposed in the vicinity of the boundary lines 2102 and 2103 of the overlapping exposure area are auxiliary patterns 2104 and 2105 that indicate the overlapping exposure area. In so doing, it becomes simple to detect the location of the overlapping exposure area when measuring. The present evaluation TEG is such that, when the circuit 2108 is processed correctly, the resistance between the pad 2106 and the pad 2107 is extremely large due to the gap 2109 and the gap 2110. However, when there occurs an irregularity in head positioning in the vertical direction as described with reference to FIG. 3A, or an irregularity in head positioning in the sub scan direction 110 as described with reference to FIG. 4A, then the circuit 2108 becomes indistinct. As a result, the gap 2109 and the gap 2110 are eliminated, as shown in FIG. 21B. In this case, the resistance between the pad 2106 and the pad 2107 is decreased. It is thus possible to detect irregularities in head positioning using this change in resistance.

The size of the gaps 2109 and 2110 are designed such that the resistance change between the pad 2106 and the pad 2107 exists in an easily-detectable range.

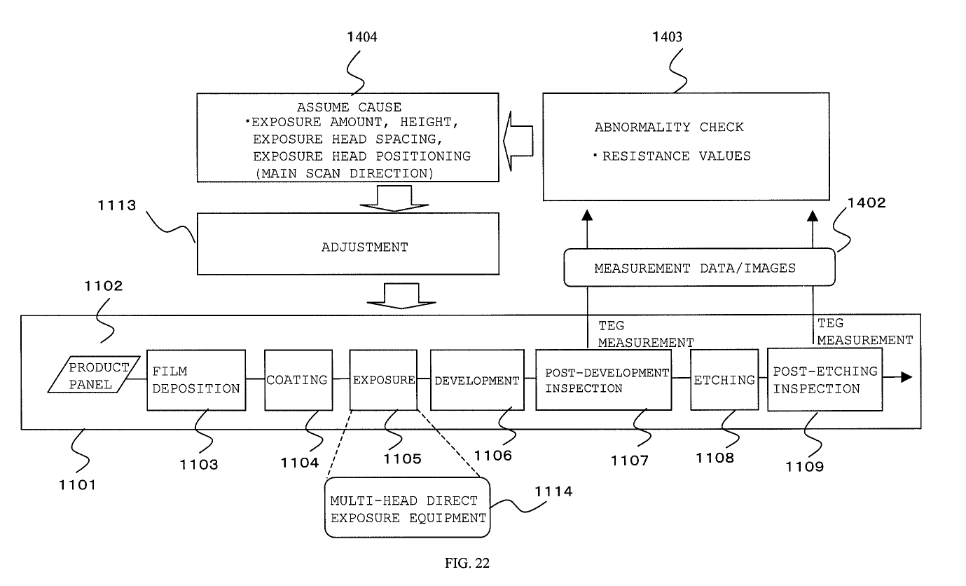

FIG. 22 is a diagram illustrating a method for manufacturing liquid crystal substrates that includes head alignment of the multi-head exposure equipment using the resistance-based evaluation TEGs. In outline this method is the same as the method for manufacturing liquid crystal substrates shown in FIG. 11 that includes head alignment of the multi-head exposure equipment using the line width-based evaluation TEGs. The present method differs in that the resistance-based evaluation TEGs are used not during the post-development inspection, but during the post-etching inspection. Moreover, the measured and collected data in this inspection consists of resistance values. Ways of summarizing the data, as well as the methods of analyzing and comparing the data of the overlapping exposure areas to the single exposure areas, are principally the same.

### Embodiment 3

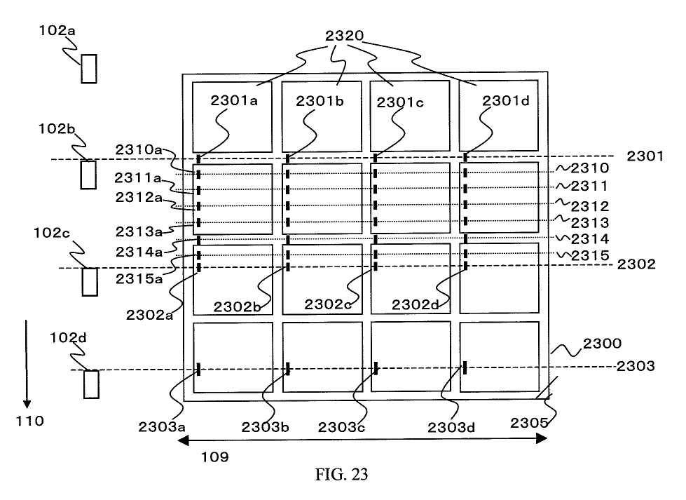

In the first embodiment, an embodiment was described wherein TEGs are placed at the head exposure area boundaries. Here, however, an example will be described wherein evaluation patterns are also disposed at the returning boundaries within the areas exposed by the same head. In addition, while in the first embodiment the evaluation patterns were disposed on the scribe lines, herein an embodiment will be described wherein evaluation patterns are also disposed in the products. When the evaluation patterns are disposed in the products, the locations of the head exposure area boundaries and the returning boundaries are known from the positions of the evaluation patterns, even after cutting the products from the substrate. For this reason, this method has the merit of making it easier to conduct defect analysis or other tests after the fact. The above will be described in conjunction with FIG. 23. The all-encompassing rectangle 2300 is a substrate subjected to exposure. When an orientation flat 2305 is positioned in the lower-right of the diagram, the main scan direction 109 of the heads is the horizontal direction in the diagram, while the sub scan direction 110 is the vertical direction in the diagram. It should be appreciated that, in practice, the stage moves in the opposite direction, thereby changing the relative positions of the heads. Product panels 2320 on the substrate are arranged in a checkered pattern upon the substrate 2300. As with the cases shown in FIGS. 1 and 12, an example is shown wherein exposure is conducted using four heads. However, in actual practice four heads are not necessary, and the number of exposure heads may be changed accordingly. Similarly, the number of times a head returns in the diagram is shown simply by way of example.

Head exposure area boundaries 2301, 2302, and 2303 are the overlapping portions of the exposure areas for each of the exposure heads, and roughly exist at an interval that matches the exposure head spacing.

The area between the head exposure area boundary 2301 and the head exposure area boundary 2302 will now be described in detail by way of example. The area between the head exposure area boundary 2301 and the head exposure area boundary 2302 is the area exposed by the exposure head 102b. Additionally, as a result of the movement of the stage, returning exposure areas 2310, 2311, 2312, 2313, 2314, and 2315 are arranged at roughly equal intervals of width equal to the movement distance 206 in the sub scan direction of the stage as shown in FIG. 2A. Evaluation patterns are disposed upon the head exposure area boundaries 2301 and 2302, as well as upon the returning boundaries 2310, 2311, 2312, 2313, 2314, and 2315. Since these head returning exposure area boundaries are arranged at intervals equal to the width of the movement distance 206 of the stage as shown in outline in FIG. 2, the boundaries are arranged at roughly equal intervals in the sub scan direction of the stage. In addition, when taking into consideration the ease of detecting the evaluation patterns, it is preferable to arrange the evaluation patterns in a roughly linear manner along the main scan direction of the stage. Consequently, as shown in the diagram, evaluation patterns 2301a, 2310a, 2311a, 2312a, 2313a, 2314a, 2315a, and 2302a are arranged at equal intervals in the sub scan direction of the stage, and are arranged in a linear manner in the main scan direction of the stage.

Hereinafter, the method for disposing the evaluation patterns on the product panels on the left side of the substrate 2300 will be described. It should be appreciated that evaluation patterns are also disposed on the other product panels between the head exposure area boundary 2301 and the head exposure area boundary 2302, specifically on the head exposure area boundaries 2301 and 2302, as well as the returning boundaries 2310, 2311, 2312, 2313, 2314, and 2315. (Reference numbers are not given for the evaluation patterns disposed upon these returning exposure area boundaries.)

Evaluation patterns are similarly disposed upon the areas exposed by the heads 102a, 102c, and 102d (not shown in the figure). When evaluation patterns are disposed as described above, a plurality of evaluation patterns become arranged at roughly equal intervals on a single product panel. The disposed width of the evaluation patterns is roughly equal to the movement distance of the stage in the sub scan direction.

The method for finding abnormalities in exposure head positioning using the evaluation patterns is as described in the first embodiment (cf. FIGS. 13 and 14).

### Embodiment 4

The methods for disposing evaluation patterns described up to this point have been for the purpose of measuring the dimensions of an evaluation pattern placed in an overlapping exposure area and an adjacent single exposure area, and thereby evaluate the imaging quality in the overlapping exposure area by the plurality of exposure heads. The method for disposing evaluation patterns to be hereinafter described is for the purpose of measuring the dimensions of an evaluation pattern placed in a single exposure area, without measuring inside an overlapping exposure area.

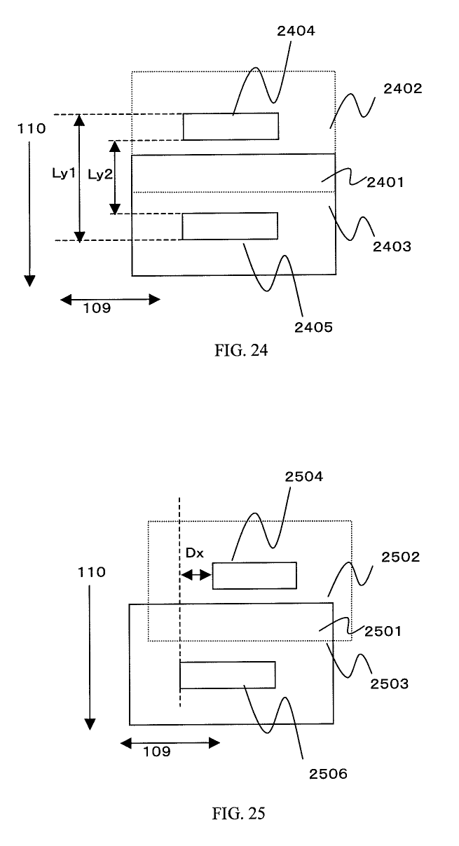

An evaluation pattern will now be described for detecting deformations occurring when the head spacing becomes misaligned, as shown in FIGS. 4 and 24. Hereinafter, this evaluation pattern will be referred to as the “opposed rectangles evaluation pattern”. An overlapping exposure area 2401 exists between a single exposure area 2402 and a single exposure area 2403. First, the distances Ly1 and Ly2 are measured between a measurement pattern 2404 disposed within the single exposure area 2405 and a measurement pattern 2402 disposed within the single exposure area 2405 disposed within the single exposure area 2403. The distance Ly1 is the distance between the outer boundaries of the two opposed rectangles, while the distance Ly2 is the distance between the inner boundaries of the two opposed rectangles. The measurement pattern 2404 and the measurement pattern 2405 are preferably rectangles. The opposed edges of these two rectangles are preferably parallel. As shown in FIG. 24, the values Ly1 and Ly2 are the measured results for the inner and outer distances between the respective patterns. Using these values Ly1 and Ly2, the distance between the measurement patterns is defined as

Ly=(Ly1+Ly2)/2

This value Ly and the predefined value Lyd in the design for disposing the measurement patterns are compared and evaluated as follows.

If Lyd=Ly, the desired dimensions have been imaged.

If Lyd<Ly, the imaged spacing is longer than the desired dimensions.

If Lyd>Ly, the imaged spacing is shorter than the desired dimensions.

By disposing upon the substrate the measurement pattern 2404 and 2405 as shown in FIG. 24, it is possible to detect head spacing misalignment of the multi-head direct exposure equipment. In addition, by disposing these patterns at the returning boundaries, alignment at the returning boundaries can be evaluated.

Next, a method will be described for detecting deformations in the case where the arrangement of heads is misaligned in the main scan direction 109, as shown in FIGS. 5 and 25. The evaluation patterns used herein are opposed rectangle evaluation patterns.

an overlapping exposure area 2501 exists between a single exposure area 2502 and a single exposure area 2503. A misalignment distance Dx is measured between a measurement pattern 2504 disposed within the single exposure area 2502 and a measurement pattern 2506 disposed within the single exposure area 2503. It is possible to detect head misalignment in the main scan direction using this value Dx.

In addition, by disposing these evaluation patterns at the returning boundary portions, it is possible to apply the present example to the detection of misalignment at the returning boundaries.

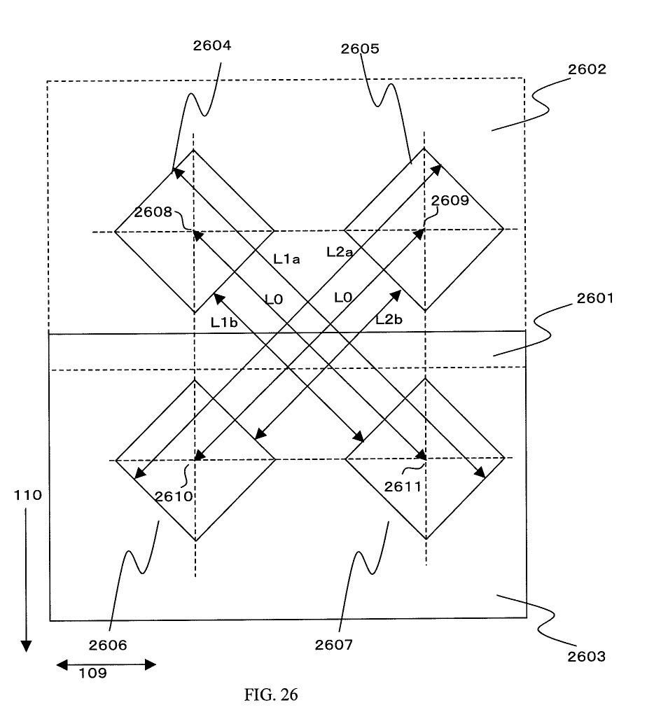

Next, a method for simultaneously detecting misalignment of two exposure heads in both the main scan direction and the sub scan direction will be described with reference to FIG. 26.

A overlapping exposure area 2601 exists between a single exposure area 2602 and a single exposure area 2603. A square 2604 and a square 2605 are diagonally disposed in the single exposure area 2602. Additionally, a square 2606 and a square 2607 are diagonally disposed in the single exposure area 2603. The patterns are imaged such that both the distance between the center 2608 of the square 2604 and the center 2611 of the square 2607, as well as the distance between the center 2609 of the square 2605 and the center 2610 of the square 2606 are an equal distance L0. In addition, the opposing edges of the square 2604 and the square 2607, as well as the opposing edges of the square 2605 and the 2606 are respectively parallel. In addition, post-measurement data processing is simple if the squares are tilted at an angle of 45 degrees with respect to the main scan direction. The center 2608 of the square 2604, the center 2609 of the square 2605, the center 2610 of the square 2606, and the center 2611 of the 2607 are also disposed so as to form a square of length L0/√2 on each side. Hereinafter, this evaluation pattern will be referred to as the diagonally-disposed square evaluation pattern.

Herein, the following quantities are measured: the distance L1a between the outer edges of the square 2604 and the square 2607, the distance L1b between the inner edges of the square 2604 and the square 2607, the distance L2a between the outer edges of the square 2605 and the square 2606, and the distance L2b between the inner edges of the square 2605 and the square 2606.

Given a pattern misalignment Dx in the main scan direction, and taking a pattern misalignment Ly in the sub scan direction to be

L1=(L1a+L1b)/2

L2=(L2a+L2b)/2

gives the following:
(1) When L1 and L2 are equal,

Ly=√2*(L1−L0), Dx=0

(2) When L1 and L2 are not equal,

Dx=R sin θ, Ly=R cos θ

wherein

R=SQRT(((L1+L2−2L0)²+(L1−L2)²)/2)

θ=Arctan((L1+L2−2L0)/(L1−L2))

The function SQRT( ) solves for the square root of the argument, and the function Arctan( ) solves for the arc tangent of the argument.

Using the diagonally-disposed square evaluation pattern, it is possible to simultaneously measure misalignments in the movement of the stage in the main scan direction, as well as positional misalignments in pattern imaging due to misalignment in the movement in the sub scan direction. By comparing these misalignment quantities to the predefined values in the design, the presence of abnormalities can be evaluated.

In addition, if the diagonally-disposed square evaluation pattern is similarly disposed spanning a returning exposure area, it is possible to detect exposure misalignments due to the back and forth movement of the stage. By disposing in this manner the disposing of the evaluation pattern becomes like that shown in FIG. 23 of the third embodiment, with the evaluation patterns arranged at roughly equal intervals on the product panels.

### Embodiment 5

In the fourth embodiment, an evaluation pattern was disposed in single exposure areas on either side of an overlapping exposure area. Here, however, a method will be described wherein an evaluation pattern is disposed within an overlapping exposure area, the method detecting misalignments in exposure head positioning as well as misalignments in exposure positioning due to erratic movement when the stages moves back and forth.

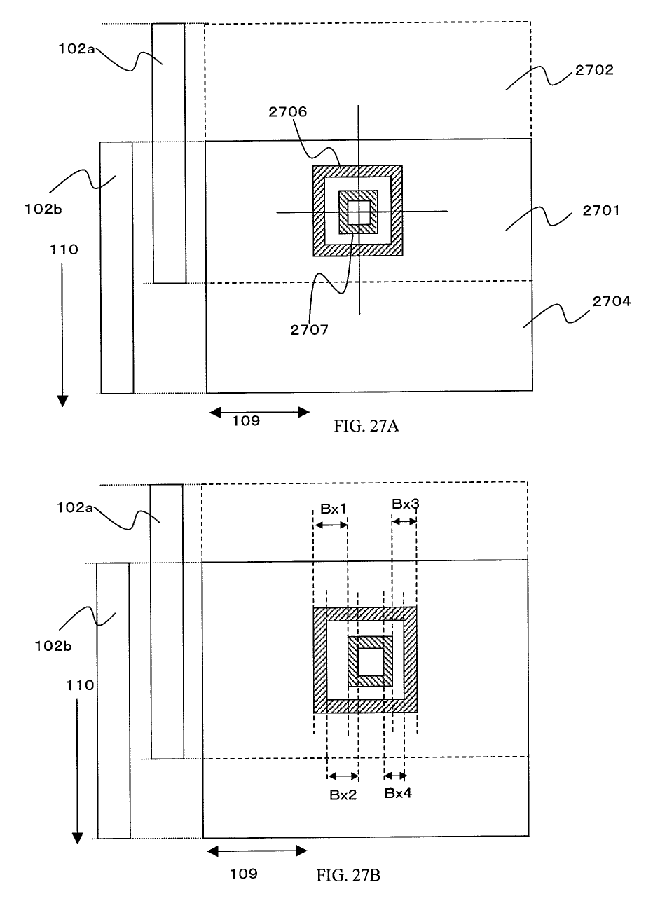

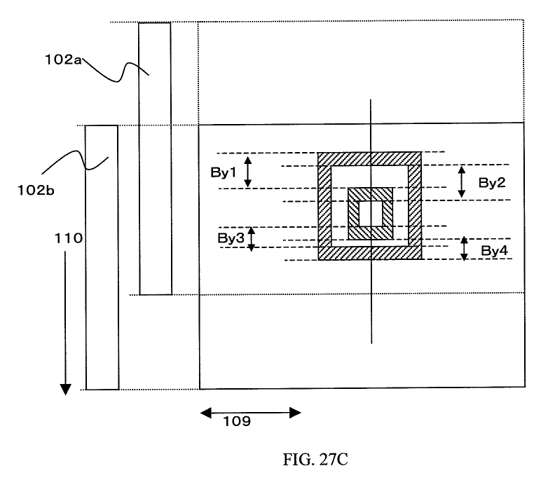

In FIG. 27A, a single exposure area 2702 is exposed by the exposure head 102a, and a single exposure area 2704 is exposed by the exposure head 102b. A overlapping exposure area 2701 is exposable by both the exposure head 102a and the exposure head 102b.

Herein, in order to detect misalignments in the arrangement of the exposure heads in the main scan direction and the sub scan direction, an outer pattern 2706 is imaged by the exposure head 102a and an inner pattern 2707 is imaged by the exposure head 102b in the overlapping exposure area 2701. In other words, patterns having a box in box shape are imaged. As shown in FIG. 27A, these two patterns are disposed such that their center positions match. However, in FIG. 27B, the quantities

Bx1 (the distance between the outer left-hand boundaries of the outer box and the inner box),

Bx2 (the distance between the inner left-hand boundaries of the outer box and the inner box),

Bx3 (the distance between the inner right-hand boundaries of the outer box and the inner box), and

Bx4 (the distance between the outer right-hand boundaries of the outer box and the inner box) are measured, and the values

BL=(Bx1+Bx2)/2

BR=(Bx3+Bx4)/2

are calculated. If BL and BR are equal, then the result is evaluated as having no misalignment in the main scan direction with respect to the positions of the outer pattern and the inner pattern. If BL is large compared to BR, then the inner pattern has been shifted to the right compared to the outer pattern, and if BL is small compared to BR, then the inner pattern has been shifted to the left compared to the outer pattern. As a result, it is possible to evaluate the imaged result of the exposure head 102a and the exposure head 102b as being misaligned in the main scan direction 109.

In addition, in FIG. 27C, the quantities

By1 (the distance between the outer upper boundaries of the outer box and the inner box),

By2 (the distance between the inner upper boundaries of the outer box and the inner box),

By3 (the distance between the inner lower boundaries of the outer box and the inner box), and

By4 (the distance between the outer lower boundaries of the outer box and the inner box)

are measured, and the values

BU=(By1+By2)/2

BD=(By3+By4)/2

are calculated. If BU and BD are equal, then the pattern is evaluated as having no misalignment in the sub scan direction with respect to the positions of the outer pattern and the inner pattern. If BU is large compared to BD, then the inner pattern has been shifted down compared to the outer pattern, and if BU is small compared to BD, then the inner pattern has been shifted up compared to the outer pattern. As a result, it is possible to evaluate the imaged result of the exposure head 102a and the exposure head 102b as being misaligned in the sub scan direction 110.

In addition, in order to detect misalignments in exposure positioning at a returning boundary area, the overlapping exposure area 2701 may be thought of as an overlapping exposure area of a returning boundary, wherein the outer pattern 2706 is imaged during the main scan in the forward direction, and the inner pattern 2707 is imaged during the main scan in the backward direction. The method for measuring is the same as the case for detecting misalignments in exposure head arrangement in the main scan direction and the sub scan direction. By performing the above, it is possible to detect exposure misalignments at the returning boundary portions. By disposing in this manner the disposing of the evaluation pattern becomes like that shown in FIG. 23 of the third embodiment, with the evaluation patterns arranged at roughly equal intervals on the product panels.

The shapes and methods for disposing the evaluation TEGs described in the foregoing first, second, third, fourth, and fifth embodiments are given merely as examples, and a variety of embodiments exists that do not depart from the spirit and effects of the present invention. Such embodiments are included within the scope of the present invention.

Moreover, while the present invention was described herein as a method for manufacturing liquid crystal display panels, the invention can also be applied to a wide range of product manufacturing processes having exposure processes therein, such as semiconductor manufacturing and printed circuit board manufacturing.

The present invention, while being devised with liquid crystal display devices in mind, can also be utilized in processes wherein substrate deformation occurring in mid-process exerts effects on process precision, such as the processes for other types of display devices, printed circuit boards, and semiconductor devices.

What is claimed is:

1. A method for manufacturing a substrate using direct exposure equipment having a plurality of exposure heads, the method comprising:
disposing test element groups (TEG) for evaluation at a head exposure area boundary on the substrate;
comparing a measured value from the evaluation TEGs within the head exposure area boundary to a measured value from the evaluation TEGs within a single exposure area, to detect a misalignment in the exposure heads; and
correcting the misalignment in the exposure heads to realize stable exposure performance of the direct exposure equipment.

2. The method for manufacturing a substrate according to claim 1, wherein the evaluation TEGs are TEGs for evaluating line width.

3. The method for manufacturing a substrate according to claim 2, wherein the line width evaluation TEGs have a length that is longer than the width of the head exposure area boundary, being line width evaluation TEGs having a linear shape intersecting the head exposure area boundary.

4. The method for manufacturing a substrate according to claim 2, wherein the line width evaluation TEGs have a linear shape and are disposed parallel to a head exposure area boundary.

5. The method for manufacturing a substrate according to claim 2, wherein the line width evaluation TEGs have a diagonal line shape that is longer than the width of the head exposure area boundary.

6. The method for manufacturing a substrate according to claim 1, wherein the evaluation TEGs are TEGs for evaluating resistance.

7. The method for manufacturing a substrate according to claim 6, wherein the TEGs for evaluating resistance have a winding shape.

8. The method for manufacturing a substrate according to claim 6, wherein the TEGs for evaluating resistance have a checkered shape.

9. The method for manufacturing a substrate according to claim 6, wherein the TEGs for evaluating resistance have a diamond shape.

10. The method for manufacturing a substrate according to claim 6, wherein the TEGs for evaluating resistance have a linear shape.

11. A method for manufacturing a substrate using direct exposure equipment having a plurality of exposure heads, the method comprising:
subjecting the substrate to exposure treatment such that evaluation patterns are respectively disposed both in an area exposed by a single exposure head and an area subject to overlapping exposure by a plurality of exposure heads; and
detecting misalignments in the exposure heads by comparing a measured value from the evaluation pattern in the area exposed by a single exposure head to a measured value from the evaluation pattern in the area subject to overlapping exposure by a plurality of exposure heads.

12. A method for manufacturing a substrate using direct exposure equipment having a plurality of exposure heads, the method comprising:
subjecting the substrate to exposure treatment such that evaluation patterns are respectively disposed in two areas exposed by single exposure heads positioned on either side of an area subject to overlapping exposure by a plurality of exposure heads; and
detecting misalignments in the exposure heads by measuring a positional relationship of the evaluation patterns respectively formed in the two single exposure areas.

13. A liquid crystal display device, comprising:
a plurality of evaluation patterns disposed so as to form linear rows, the rows being arranged at roughly equal intervals.

14. The liquid crystal display device according to claim 13, wherein the evaluation patterns are made up of four rectangles tilted at 45 degree angles.

15. The liquid crystal display device according to claim 13, wherein the evaluation patterns are made up of two opposing rectangles.

16. The liquid crystal display device according to claim 13, wherein the evaluation patterns form a box-in-box shape.
